(19) United States
(12) Patent Application Publication
(10) Pub. No.: US 2008/0122469 A1
(43) Pub. Date: May 29, 2008

(54) Probe card for testing image-sensing chips

(75) Inventor: Sheng-Feng Lu, Hsin-Chu City (TW)

Correspondence Address: BACON & THOMAS, PLLC, 625 SLATERS LANE, FOURTH FLOOR, ALEXANDRIA, VA, 22314, US

(73) Assignee: VISERA TECHNOLOGIES, COMPANY LTD., HSIN-CHU CITY (TW)

(21) Appl. No.: 11/604,865

(22) Filed: Nov. 28, 2006

(51) Int. Cl. G01R 1/073

(52) U.S. Cl. 324/761; 324/754

(57) ABSTRACT

A probe card for testing an image-sensing chip includes a circuit board having a first surface, a second surface, and an opening cut through the first and second surfaces for the passing of a test light, a guide member, and probes. The guide member is mounted on the second surface of the circuit board and provided with through holes. The probes each have a first end respectively electrically connected to the circuit board adjacent to the opening and a second end respectively inserted through the through holes of the guide member to the outside of the guide member for electrically connecting contacts of an image-sensing chip to be tested.

### BACKGROUND OF THE INVENTION

1. Field of the Invention

The present invention relates to probe cards and more particularly, to a probe card for use in testing image-sensing chips.

2. Description of the Related Art

A probe card for use in testing a semiconductor chip is set between the test machine and the chip with the probes of the probe card respectively pressed on the respective contact pads at the test chip. During test, test signal is transmitted between the test machine and the test chip through the probe card. By means of a signal processing and computing procedure run through a test program installed in the test machine, the functioning of the test chip is examined.

Regular probe cards include two types, namely, the cantilever type and the vertical type. A cantilever type probe card, such as the disclosure of U.S. Pat. No. 5,055,778, comprises a circuit board and a plurality of probes. In addition, the circuit board of a specific cantilever type probe card, such as the disclosure of U.S. Pat. No. 5,751,157, is provided with a center opening. The probes are connected to the circuit board through a locating ring that is mounted in the center opening of the circuit board, such that the probes suspend from the locating ring around the center opening of the circuit board. When using a cantilever type probe card to test an image-sensing chip, for example, a CMOS (complementary metal-oxide semiconductor) image-sensing chip, the probes are respectively pressed on the respective contacts at the image-sensing chip, and then the test light is emitted through the center opening of the circuit board onto the optical induction zone of the image-sensing chip, causing the optical induction zone of the optical image-sensing chip to induce an electric signal, which is then provided to the test machine through the probe card for processing. Due to structural limitation, a cantilever type probe card is not suitable for testing semiconductor chips having a high pin count or performing a high frequency test procedure. Therefore, a vertical type probe card is used for testing semiconductor chips having a high pin count or performing a high frequency test procedure.

However, the circuit board of a conventional vertical type probe card does not have an opening for the passing of test light. For example, a conventional vertical type probe card disclosed in U.S. Pat. No. 6,300,783 is provided with through holes, as denoted by reference numeral 861 in the U.S. Pat. No. 6,300,783, for the insertion of the probes, but no opening for the passing of testing light. Therefore, conventional vertical type probe cards are not suitable for use in testing image-sensing chips.

### SUMMARY OF THE INVENTION

The present invention has been accomplished under the circumstances in view. It is therefore the main object of the present invention to provide a vertical type probe card, which allows direct pass of a test light so that the probe card is usable for use in testing image-sensing chips.

To achieve this object of the present invention, the probe card comprises a circuit board having a first surface, a second surface and an opening cut through the first surface and the second surface, a guide member mounted on the second surface of the circuit board, and a plurality of probes. The guide member has a plurality of through holes. The probes are made of an electrically conductive material, each having a first end respectively electrically connected to the circuit board adjacent to the opening and a second end respectively inserted through the through holes of the guide member to the outside of said guide member for electrically connecting contacts of an image-sensing chip to be tested. Accordingly, the test light can pass directly through the opening of the circuit board to the chip to be tested, and therefore the probe card is practical for use in testing an image-sensing chip.

### BRIEF DESCRIPTION OF THE DRAWINGS

FIG. 1 is a schematic sectional view of a probe card according to a first preferred embodiment of the present invention.

FIG. 2 is schematic view of the present invention, showing an application example of the probe card.

FIG. 3 is a schematic sectional view of a probe card according to a second preferred embodiment of the present invention.

### DETAILED DESCRIPTION OF THE INVENTION

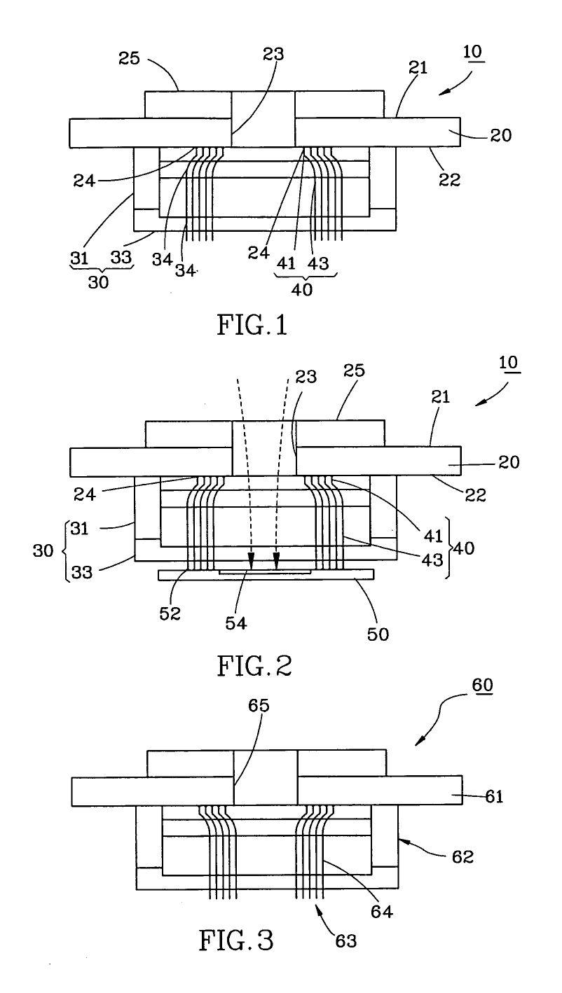

Referring to FIGS. 1 and 2, a probe card 10 is shown for use in testing image-sensing chips, comprising a circuit board 20, a guide member 30, and probes 40. The circuit board 20 has a first surface 21, a second surface 22 opposite to the first surface 21, and an opening 23 cut through the first surface 21 and the second surface 22. The second surface 22 has electric connection members 24 arranged adjacent to the opening 23 at locations corresponding to the contacts 52 of a CMOS image-sensing chip 50 to be tested. A reinforcing ring 25 is provided at the first surface 21 in a coaxial manner relative to the opening 23 to reinforce the structural strength of the circuit board 20.

The guide member 30 has a top frame 31 and a bottom frame 33. The top frame 31 and the bottom frame 33 are arranged in a stack, each having a plurality of vertical through holes 34. The top frame 31 is mounted on the second surface 22 of the circuit board 20 corresponding to the opening 23,

The probes 40 are metal conductive rod members each having a straight vertical section 41 and a springy section 43. The springy section 43 is formed integral with one end of the straight vertical section 41, having a curved profile. The straight vertical sections 41 of the probes 40 are respectively soldered to the electric connection members 24 at the second surface 22 of the circuit board 20. The springy sections 43 of the probes 40 are respectively downwardly extending from the respective straight vertical sections 41 and respectively inserted through the through holes 34 of the frames 31 and 33 of the guide member 30 over the bottom side of the guide member 30. The probes 40 extend in axial direction relative to the opening 23 of the circuit board 20, having the respective springy sections 43 symmetrically arranged at two sides and curved outwards relative to the opening 23 and then extending vertically downwards.

Referring to FIG. 2 again, when the probe card 10 is sued in testing a CMOS image-sensing chip 50, the springy sections 43 of the probes 40 that protrude over the bottom side of the guide member 30 are respectively pressed on the contacts 52 of the CMOS image-sensing chip 50 to electrically connect the contacts 52 of the CMOS image-sensing chip 50 to the circuit board 20. At this time, the optical induction zone 54 of the CMOS image-sensing chip 50 lays open to the opening 23 of the circuit board 20. During test, test light that comes from the top side of the circuit board 20 passes through the opening 23 of the circuit board 20 and the center area of the guide member 30 to the CMOS image-sensing chip 50 to induce the CMOS image-sensing chip 50, thereby causing the optical induction zone 54 to produce an electric signal, which is then received by the test machine through the probes 40 and the circuit board 20 for LVDS (Low Voltage Differential Signaling) chip quality test. Because the probes 40 are directly installed in the circuit board 20 and substantially vertically pressed on the CMOS image-sensing chip 50, transmission of signal at a relatively higher frequency between the CMOS image-sensing chip 50 and the circuit board 20 is allowed. Further, because the probes 40 are symmetrically arranged at two sides relative to the opening 23, the probes 40 at one side will not touch the probes 40 at the other side and the probes 40 at both sides will not block the light path when they are pressed on the CMOS image-sensing chip 50 and caused to buckle.

Base on the structural features described above, the probe card allows the test light to pass directly through the circuit board to the test sample, and therefore the probe card is practical for use in testing an image-sensing chip.

FIG. 3 shows a probe card according to the second embodiment of the present invention. Similar to the aforesaid first embodiment of the present invention, the probe card 60 of this second embodiment is comprised of a circuit board 61, a guide member 62, and probes 63. The main feature of this embodiment is that the springy sections 64 of the probes 63 are respectively curved inwards toward the opening 65 and then extending vertically downwards.

Although particular embodiments of the invention have been described in detail for purposes of illustration, various modifications and enhancements may be made without departing from the spirit and scope of the invention. Accordingly, the invention is not to be limited except as by the appended claims.

1. A probe card comprising:
a circuit board having a first surface, a second surface, and an opening cut through said first surface and said second surface;
a guide member mounted on the second surface of said circuit board, said guide member having a plurality of though holes and an open center area; and
a plurality of probes made of an electrically conductive material, said probes each having a first end respectively electrically connected to said circuit board adjacent to said opening and a second end respectively inserted through the through holes of said guide member to the outside of said guide member;
wherein the opening of said circuit board, the open center area of said guide member, and said probes are arrange to provide an unobstructed light path between the first surface of said circuit board and a surface of a semiconductor chip when the semiconductor chip is placed in contact with said probes.

2. The probe card as claimed in claim 1, wherein said probes are symmetrically arranged at two sides relative to said opening of said circuit board.

3. The probe card as claimed in claim 1, wherein said proves each have a straight section connected to said circuit board and a springy section formed integral with one end of said straight section and extending toward said guide member.

4. The probe card as claimed in claim 3, wherein said springy section curves from one end of said straight section; said probes extend in axial direction relative to the opening of said circuit board, having the respective springy sections symmetrically arranged at two sides and curved outwards relative to the opening of said circuit board.

5. The probe card as claimed in claim 3, wherein said springy section curves from one end of said straight section; said proves extend in axial direction relative to the opening of said circuit board, having the respective springy sections symmetrically arranged at two sides and curbed inwards toward the opening of said circuit board.

6. The probe card as claimed in claim 1 further comprising a reinforcing ring mounted on said first surface of said circuit board in a coaxial manner relative to the opening of said circuit board.

7. The probe card as claimed in claim 1, wherein said guide member comprises a top frame and a bottom frame arranged in a stack, and the through holes of said guide member are formed in said top frame and said bottom frame, said top frame being fastened to the second surface of said circuit board corresponding to the opening of said circuit board.
